(19) United States
(12) Patent Application Publication
(10) Pub. No.: US 2006/0240666 A1
(43) Pub. Date: Oct. 26, 2006

(54) METHOD OF FORMING SILICIDE

(76) Inventors: Chao-Ching Hsieh, Hsinchu Hsien (TW); Yi-Yiing Chiang, Taipei City (TW); Chien-Chung Huang, Taichung Hsien (TW); Po-Chao Tsou, Taipei County (TW); Kirk Hsu, Hsinchu Hsien (TW); Tony Lin, Hsinchu City (TW); Le-Tien Jung, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,891

(22) Filed: Apr. 20, 2005

(51) Int. Cl. H01L 21/44

(52) U.S. Cl. 438/655; 438/682; 438/656

(57) ABSTRACT

A method of forming silicide is described. A layer of refractory metal is deposited on a substrate, and then a first annealing process is performed to form silicide, followed by removal of unreacted metal. Next, a species implanting process is carried out to implant species of neutral atoms into the silicide to break up lattice structure of the silicide, so that the problem of junction leakage induced by spiking and piping diffusion under high temperature during a subsequent second annealing process is avoided.

### BACKGROUND OF THE INVENTION

1. Field of the Invention

The present invention relates to a method of forming silicide, and more particularly to a method of forming self-aligned silicide, or silicide.

2. Description of the Related Art

A transistor of metal oxide semiconductor (MOS), as a semiconductor device, consists of three poles of gate, source, and drain. Earlier, MOS consists of a metal layer, silicon oxide layer and substrate, but most metals cannot adhere properly on the silicon oxide layer. Thus, polysilicon that shows better adhesion property has been proposed to replace the metals in MOS. However, resistivity of polysilicon is too high, such that even if a doped polysilicon layer is used, the resistivity of which is still undesirably high and thus polysilicon is not suitable for replacing the metal layer. To solve such problem, an additional silicide layer with a thickness comparable to that of the polysilicon is added on the polysilicon, so that the silicide layer with higher conductivity and the polysilicon layer are combined to form the conduction layer.

Conventionally, silicide layer is formed via a thermal process from a metal film. The metal film is first deposited on a substrate via an evaporating or sputtering process, and a rapid annealing process is then performed, so that under an atmosphere of nitrogen or argon in high purity, the metal film reacts with silicon at the junction to form the silicide layer.

Silicide has been increasingly used for manufacturing integrated circuits since silicide is high in melting point, low in stability and low in resistivity, which properties is desirable for increasing the driving current and operating speed of the semiconductor device. Besides, because of the property of self-alignment, a special kind of silicide, or salicide (self-aligned silcide), is now widely used for manufacturing integrated circuits.

On the other hand, with the miniaturization of integrated circuits, gate line width is continuously reduced. As a result, a so-called narrow line width effect is induced on the silicide such as titanium silicide. In other words, when the line width is reduced, sheet resistance of the titanium silicide generated at the gate will be increased significantly. For this reason, other supplemental materials begin to be used, among which CoSi₂ and NiSi are most popular ones.

During a conventional process of forming the self-aligned silcide, however, silicon on the source/drain will be consumed and be converted to silicide. Therefore, with the trend that line width of semiconductor device is further reduced, the problem of junction leakage will be even worse due to consumption of the source/drain.

In another conventional process, on the other hand, a silicon species is implanted into the substrate before deposition of titanium, so as to destroy lattice structure of silicon in the substrate for subsequent processes. This process, however, is unsuitable if nickel is used for implantation, because under a very high temperature during a subsequent second annealing process, NiSi will be converted to NiSi₂; which will in turn cause junction leakage due to spiking and piping diffusion. If the second annealing process is carried out under a relatively lower temperature, however, amorphous silicon of the substrate cannot be recrystallized to form crystalline silicon.

### SUMMARY OF THE INVENTION

In view of the above, the present invention is directed to provide a method of forming silicide so as to avoid the problem of conversion of NiSi to NiSi₂, which may cause junction leakage due to spiking and piping diffusion under high temperature in a subsequent second annealing process.

The present invention provides a method of forming silicide according to an embodiment of the present invention. A silicon substrate has a gate structure and a source/drain formed thereon, and a space wall is formed on the sidewalls of the gate. A metal layer is then deposited respectively on the gate structure, source/drain and space wall. Next, a thermal process is carried out to cause the metal layer to react with the source/drain to form silicide. Afterwards, portions of the unreacted metal layer are removed, and a species implanting process is performed on the silicide. Finally, a second thermal process is carried out to change the phase of the silicide to a phase with low resistivity.

According to the preferred embodiment, the metal layer is made of, for example, titanium, cobalt, or nickel. The first thermal process is, for example, a rapid thermal process. The process of removing unreacted metal layer is, for example, a selective wet etching process. Furthermore, the species used in the species implanting process is, for example, neutral atoms of silicon, argon, xenon, germanium, or nitrogen. In a 0.065 μm process with silicon as the implanted species, the implanting energy is tens of KeV, and the dosage is about 1×101³ to 1×10¹⁸ atom/cm². The second thermal process can be also a rapid thermal process.

The present invention also provides another method of forming silicide according to another preferred embodiment of the present invention. First, a metal layer is deposited on a silicon structure. Next, a first thermal process is carried out to induce the metal layer to react with the silicon structure to form silicide. Unreacted portions of the metal layer are removed. A species implanting process is then carried out on the silicide. A second thermal process is further performed to change the phase of the silicide to a phase with low resistivity.

According to the preferred embodiment, the silicon structure is, for example, a silicon wire, or a doped region mainly consisting of silicon. The metal layer is made of, for example, titanium, cobalt, or nickel. The first thermal process is, for example, a rapid thermal process. The species used in the species implanting process is, for example, neutral atoms of silicon, argon, xenon, germanium, or nitrogen. When silicon is used as the implanted species, the implanting energy is tens of KeV, and the dosage is about 1×10¹³ to 1×10¹⁸ atom/cm². Furthermore, the second thermal process can be also a rapid thermal process.

The present invention uses the silicon implanting process to implant neutral atoms into the silicide (NiSi) so that NiSi will not be converted to NiSi₂ under a high temperature during the second thermal process and that the problem of junction leakage induced by spiking and piping diffusion is avoided.

It is to be understood that both the foregoing general description and the following detailed description are exemplary, and are intended to provide further explanation of the invention as claimed.

### BRIEF DESCRIPTION OF THE DRAWINGS

FIGS. 1A to 1E are sectional views illustrating a method of forming silicide according to a preferred embodiment of the present invention.

FIGS. 2A to 2D are sectional views illustrating a method of forming silicide according to another preferred embodiment of the present invention.

FIGS. 3A to 3E are sectional views illustrating a method of forming silicide according to yet another preferred embodiment of the present invention.

### DESCRIPTION OF THE PREFERRED EMBODIMENTS

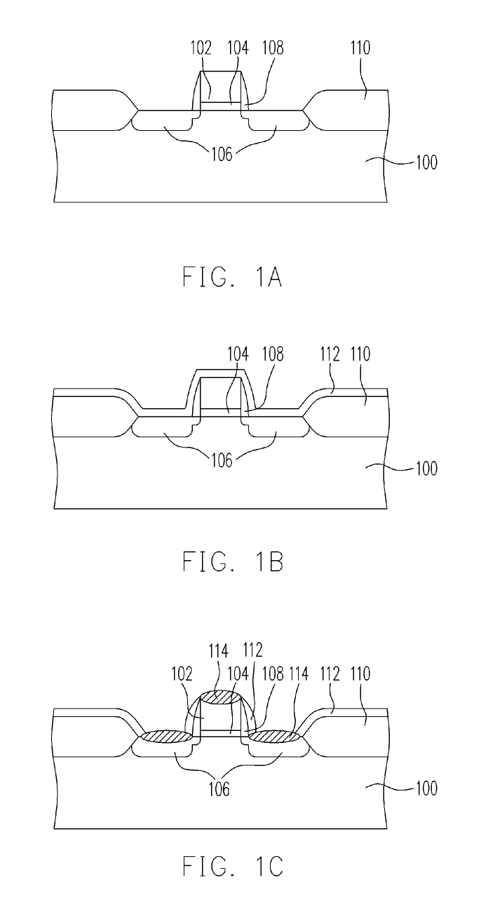

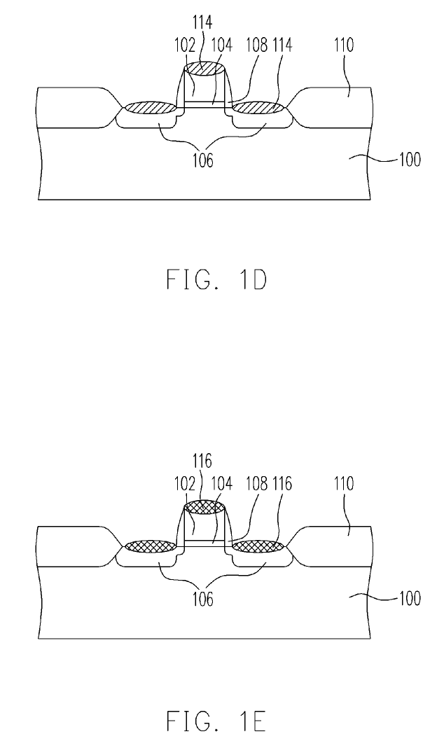

FIGS. 1A to 1E show a method of forming silicide according to a preferred embodiment of the present invention. As shown in FIG, 1A, a silicon substrate 100 having an active area defined as an insulation structure 110 is provided. The insulation structure 110 is, for example, a field oxide layer formed via local thermal oxidation or a shallow trench structure formed via shallow trench insulating method. A metal oxide semiconductor transistor is formed in the active area, whereas the transistor includes a source/drain 106, gate 102 and gate oxide layer 104 under the gate 102, and a space wall 108 is formed on sidewalls of the gate 102.

Next, Referring to FIG. 1B, a metal layer 112 is then deposited on the substrate 100. Here, the metal layer 112 is made of, for example, refractory metal such as titanium, cobalt, or nickel.

Referring to FIG. 1C, a first annealing process through a rapid thermal process, an isothermal process or a hot plate process is performed under a nitrogen atmosphere at about 200˜70° C. Here, the metal layer 112 reacts with polysilicon on the gate 102 and mono-crystalline silicon on the source/drain 106 to form silicide 114, such as titanium silicide, cobalt silicide, or nickel silicide, whereas portions of the metal layer 112 on the space wall 108 and insulation structure 110 are not reacted.

Referring to FIG. 1D, the unreacted portions of metal layer 112 are removed via, for example, a selective wet etching process. Afterwards, species implantation is performed on the silicide 114 to break up lattice structure of the silicide 114, wherein the species implanted is selected from the group of neutral atoms consisting of silicon, argon, xenon, germanium, and nitrogen. For example, the implanted species is silicon, the implanting energy is tens of KeV, and the dosage is about 1×10¹³ to 1×10¹⁸ atom/cm².

Finally referring to FIG. 1E, a second annealing process through rapid heating is carried out under a nitrogen atmosphere at about 400-900° C., to change the phase of the silicide 114 to form low resistivity silicide 116. Since the species implanting process has already been performed after the first annealing process for break up crystalline structure of the silicide 114, the silicide will not be reacted to form NiSi₂ at such high temperature during the second annealing process, and the problem of junction leakage induced by spiking and piping diffusion under high temperature is avoided.

In the above embodiment, metal oxide semiconductor is used to illustrate the method of this invention. The scope of this invention, however, is not so limited. The methods of this invention can be used for forming other types of silicon structures, such as silicon wires and doped regions mainly consisting of silicon. Such processes are described in detail in the following.

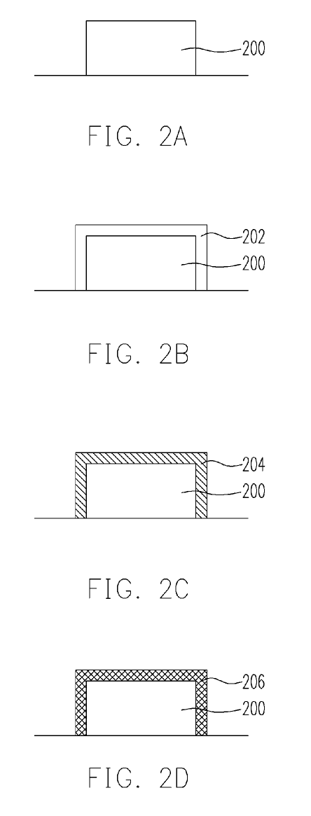

FIGS. 2A to 2D illustrate a method of forming silicide according to another preferred embodiment of the present invention, wherein the method is used to form a silicon structure such as a silicon wire. As shown in FIG. 2A, a silicon structure 200, such as a silicon wire, is provided. Referring then to FIGS. 2B and 2C, a metal layer 202 is deposited on the silicon structure 200. The metal layer 202 is made of, for example, titanium, cobalt, or nickel. Next, a first thermal process, such as a rapid thermal process, an isothermal process or a hot plate process, is performed to cause the metal layer 202 to react with the silicon structure 200 forming silicide 204.

Referring to FIG. 2D, a species implanting process is performed on the silicide 204, whereas the implanted species is, for example, neutral atoms of silicon, argon, xenon, or germanium. For example, the implanted species is silicon, the implanting energy is tens of KeV, and the dosage is about 1×10¹³ to 1×10¹⁸ atom/cm².

The unreacted portions of the metal layer 202 is subsequently removed. Finally, a second thermal process, such as a rapid thermal process, is performed to change the phase of the silicide 204 to form low resistivity silicide 206.

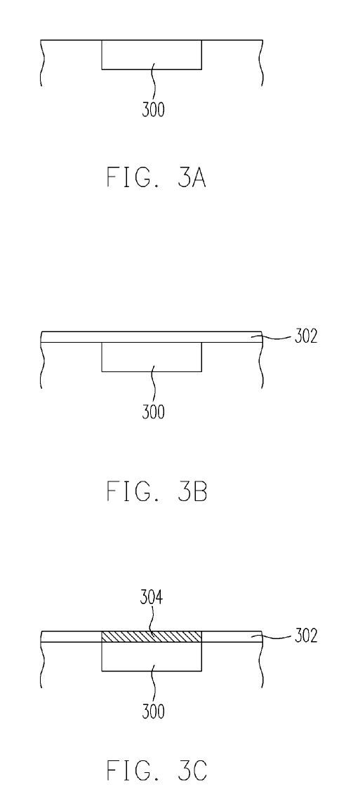

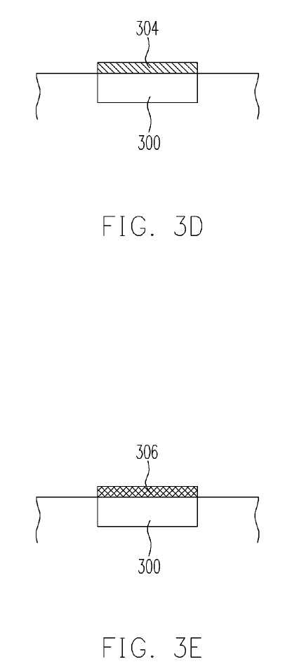

FIGS. 3A to 3E illustrate a method of forming silicide according to yet another preferred embodiment of the present invention, wherein the method is used for forming a silicon structure such as a doped region. As shown in FIG. 3A, a silicon structure 300, such as a doped region mainly consisting of silicon, is provided. Referring then to FIG. 3B, a metal layer 302 is deposited on silicon structure 300. The metal layer 302 is made of, for example, refractory metal such as titanium, cobalt, or nickel. Next, a first thermal process, such as a rapid thermal process, an isothermal process or a hot plate process, is performed to cause the metal layer 302 to react with the silicon structure 300 forming silicide 304.

Referring to FIG. 3D, the metal layer 302 is removed. A species implanting process is then performed on the silicide 304, whereas the implanted species is, for example, neutral atoms of silicon, argon, xenon, or germanium. For example, the implanted species is silicon, the implanting energy is tens of KeV, and the dosage is about 1×10¹³ to 1×10¹⁸ atom/cm².

Finally referring to FIG. 3E, a second thermal process, such as a rapid thermal process, is performed to cause the silicide 304 to have phase conversion to form low resistance silicide 306.

According to the foregoing methods of forming silicide, a species implanting process is carried out to implant the species into the silicide and break up lattice structure of the silicide, so that the problem of junction leakage induced by spiking and piping diffusion under high temperature during a subsequent second annealing process is avoided.

It will be apparent to those skilled in the art that various modifications and variations can be made to the embodiments of the present invention without departing from the scope or spirit of the invention. In view of the foregoing, it is intended that the present invention covers modifications and variations of this invention provided they fall within the scope of the following claims and their equivalents.

1. A method of forming silicide, comprising:
providing a silicon substrate having a gate and a source/drain formed thereon, a space wall being formed on sidewalls of the gate;
depositing a metal layer on the gate, the source/drain and the space wall, wherein the metal layer is made of nickel;
performing a first thermal process for the metal layer reacting with the gate and the source/drain to form a silicide;
removing unreacted portions of the metal layer;
performing a species implanting process to implant species of neutral atoms into the silicide; and
performing a second thermal process to induce a phase change in the silicide for the silicide being low in resistivity.

2. (canceled)

3. The method according to claim 1, wherein the first thermal process is a rapid thermal process, an isothermal process or a hot plate process.

4. The method according to claim 1, wherein the step of removing the unreacted portions of the metal layer includes selective wet etching.

5. The method according to claim 1, the species of neutral atoms is selected from the group consisting of silicon, argon, xenon, germanium, and nitrogen.

6. The method according to claim 5, wherein the species is silicon and implanting energy is tens of KeV, and dosage of silicon is about 1×10¹³ to 1×10¹⁸ atom/cm².

7. The method according to claim 1, wherein the second thermal process is a rapid thermal process, an isothermal process or a hot plate process.

8. A method of forming silicide, comprising:
providing a silicon structure;
depositing a metal layer on the silicon structure, wherein the metal layer is made of nickel;
performing a first thermal process for the metal layer reacting with the silicon structure to form a silicide;
performing a species implanting process to implant species of neutral atoms into the silicide; and
performing a second thermal process to induce a phase change in the silicide for the silicide being low in resistivity.

9. The method according to claim 8, wherein the silicon structure is a silicon wire, or a doped region mainly consisting of silicon.

10. (canceled)

11. The method according to claim 8, wherein the first thermal process is a rapid thermal process, an isothermal process or a hot plate process.

12. The method according to claim 8, the species of neutral atoms is selected from the group consisting of silicon, argon, xenon, germanium, and nitrogen

13. The method according to claim 12, wherein the species is silicon and implanting energy is tens of KeV, and dosage of silicon is about 1×10¹³ to 1×10¹⁸ atom/cm².

14. The method according to claim 8, wherein the second thermal process is a rapid thermal process, an isothermal process or a hot plate process.
